(19) United States
(12) Patent Application Publication
(10) Pub. No.: US 2006/0292705 A1
(43) Pub. Date: Dec. 28, 2006

(54) Method and process for fabricating read sensors for read-write heads in mass storage devices

(75) Inventors: Hariharakeshave S. Hegde, Little Neck, NY (US); Ming Mao, Pleasanton, CA (US); Boris Druz, Brooklyn, NY (US); Adrian J. Devasahayam, Commack, NY (US)

Correspondence Address: WOOD, HERRON & EVANS, LLP, 2700 CAREW TOWER, 441 VINE STREET, CINCINNATI, OH, 45202, US

(73) Assignee: Veeco Instruments Inc., Woodbury, NY (US)

(21) Appl. No.: 11/166,322

(22) Filed: Jun. 24, 2005

(51) Int. Cl. H01L 21/00

(52) U.S. Cl. 438/3

(57) ABSTRACT

Method and process for fabricating a device structure for a read head of a mass storage device. A polish stop layer formed of a relatively hard material, such as diamond-like carbon, is positioned between a layer stack and a resist mask used to mask regions of the layer stack during ion milling that removes portions of the layer stack to define a read sensor. The resist mask is removed, after the read sensor is defined, by a planarization process, which eliminates the need to lift-off the resist mask with a conventional chemical-based process. An electrical isolation layer of a material, such as Al₂O₃, is formed on the masked read sensor. In addition or alternatively, the electrical isolation layer may be formed using an atomic layer deposition (ALD) process performed at an elevated temperature that would otherwise hard bake the resist mask.

### FIELD OF THE INVENTION

The present invention relates to read-write heads for mass storage devices, and particularly to methods and processes for manufacturing read sensors used in read heads of mass storage devices.

### BACKGROUND OF THE INVENTION

Magnetic recording is a mainstay of the information-processing industry. Memory storage devices, like magnetic disk drives, include a disk or platter covered by a thin layer of recording media on which magnetically-encoded data can be written, stored, and later retrieved for use. Generally, a write sensor in a write head writes discrete bits of magnetically-encoded data in radially-spaced, concentric circular tracks in the recording media. The magnetically-encoded data, which is stored by the recording media in a binary state given by the direction of the local magnetic field, is read using a read sensor in a read head. The read and write heads are connected to circuitry that operates under computer control to implement the writing and reading operations.

The areal recording density of the recording media is limited by the critical dimension or minimum feature size of the read-write head and by the constituent material forming the recording media. As the critical dimension of the read sensor and write sensor in the read-write head drive decreases, the areal recording density of the recording media rises. However, conventional longitudinal or current-in-plane (CIP) spin-valve read sensors used in read-write heads cannot produce an adequate output amplitude as the critical dimension of the read head is reduced into deep sub-micron critical dimensions. Consequently, read sensors having a current-perpendicular-to-plane (CPP) geometry have replaced the conventional CIP spin-valve read sensors in high-density memory storage devices with “perpendicular” recording media, which have been found to be superior to “longitudinal” recording media in achieving very high bit densities. Conventional CPP read sensors include exchange biased spin-valve or giant magnetoresistance (GMR), ferromagnetic/nonmagnetic ([FM/NM]ₙ) multi-layer, and tunnel magnetoresistive (TMR) type architectures.

With reference to FIG. 1, magnetic disk drives typically integrate a read head 10 and a write head 13 into a unified read-write head carried on a movable slider 15, which is suspended from an actuator arm 17 above a platter 19. When the platter 19 rotates, the aerodynamically shaped slider 15 rides on a cushion of air produced by an air-bearing surface 21 at a well-controlled distance on the order of tens of nanometers just above the recording media of the rotating platter 19. Without contacting the rotating platter 19, an actuator (not shown) swings the actuator arm 17 to place the read and write heads 10, 13 of the read-write head over a selected track on the rotating platter 19.

With reference to FIG. 2A, the read head 10 (FIGS. 1, 2B) may be produced using thin-film deposition techniques. In particular, a layer stack (not shown) of the requisite materials for forming a read sensor 12 of the read head 10 are formed on a lower electrode 18. A bi-layer resist mask 23 is then formed on the layer stack that masks the prospective locations for each of a plurality of read sensors 12. The bi-layer resist mask 23 includes an upper resist layer 23b and a lower resist layer 23a is undercut relative to the upper resist layer 23b. The undercut advantageously limits re-deposition of milled material and promotes clean lift-off. The masked layer stack is ion milled at a high incidence angle to remove portions of the layer stack unprotected by the bi-layer resist mask 23. After ion milling, the resulting read sensor 12 is bounded by an inclined sidewall 24 that converges vertically to define a plateau-like upper surface.

The substrate supporting the bi-layer resist mask 23 and the read sensor 12 are then covered by blanket depositions of a hard biasing (HB) layer 20 (FIG. 2B) and an insulating layer 22 (FIG. 2B). In a conventional lift-off process, the bi-layer resist mask 23 is then chemically stripped. This lift-off process removes excess portions of the HB layer 20 and insulating layer 22 overlying bi-layer resist mask 23 and, thereby, defines the boundaries of the HB layer 20 and isolation layer 22 adjacent to the sidewall 24 of read sensor 12. The residual isolation layer 22 operates as a gap layer in the read head 10. The lift-off process also reveals the plateau atop the read sensor 12 for establishing an electrical contact between the uppermost layer of the read sensor 12 and an upper electrode 16 (FIG. 2B).

As shown in FIG. 2B, the CPP read head 10 includes the ion milled read sensor 12, which features a sensing layer or free layer 14, the upper electrode 16, and the lower electrode 18. The free layer 14 is longitudinally stabilized by the HB layer 20, which is composed of one or more layers of a “hard” magnetic material. The effectiveness of the hard biasing is determined by the Mrt ratio between the free layer 14 and the HB layer 20, which is typically greater than two (2) memu per cm², and the physical separation and the degree of the vertical alignment between the free layer 14 and the HB layer 20. The read sensor 12 is electrically isolated from the HB layer 20 by the intervening isolation layer 22 composed of an electrical insulator, such as alumina (Al₂O₃).

Common methods for depositing the electrical insulator to form isolation layer 22 include collimated deposition at room temperature by ion beam deposition (IBD) or physical vapor deposition (PVD) using dual collimated magnetron sputtering. Generally, the step coverage (i.e., the ratio of dimension “a” of isolation layer 22 to the dimension “b” of layer 22 as defined below) on a sidewall 24 of read sensor 12 using a collimated PVD process is limited to a range of about 15 percent to 30 percent, depending on the specific etch wall angles on the sidewall 24 as increasing the steepness of the sidewall 24 decreases the step coverage. In other words, the thickness of the isolation layer tapers along the height of the sidewall 24 and is significantly thicker in field regions than on the sidewall 24. Generally, depositing the isolation layer 22 by an IBD process improves step coverage on the sidewall 24 of the read sensor 12 than comparable depositions with a collimated PVD process. However, the step coverage available with IBD processes is still limited to a maximum of about 60 percent, again depending on the specific etch wall angles on the sidewall 24.

Because of the poor step coverage provided by either IBD or PVD processes, the electrical insulator in the deposited isolation layer 22 is significantly thicker in a field region distant from the read sensor 12 than on the sensor sidewall 24. A typical difference between the thickness, a, of isolation layer 22 on sidewall 24 in the vicinity of free layer 14 and the thickness, b, of isolation layer 22 in the field region is a factor of three or more. For instance, depositing a 50 Å isolation layer 22 on the sensor sidewall 24 often results in at least a 150 Å to 200 Å thick isolation layer 22 in the field region.

For a typical TMR sensor stack, the thickness difference of the isolation layer 22 in the field region and on the sensor sidewall 24 results in poor alignment of the HB layer 20 to the free layer 14. The geometrical offset due to the thickness difference gives rise to high surface topography with respect to the read sensor 12, resulting in an upward flaring of the read gap, which leads to poor read performance from side reading. The upward flaring of the read gap, generally indicated by reference numeral 26 and visible in FIG. 2B, arises from misalignment of the HB layer 20 with the free layer 14 due to the thicker field insulator (“b”) in isolation layer 22. The thickened field region of isolation layer 22 is required in order to meet the minimum thickness of alumina at the sidewall position, “a”, for adequate electrical isolation. Because of the thickened field region, the midplane of the HB layer 20 is located at a horizontal level significantly lower than the midplane or side edges of the free layer 14. The stability of the free layer 14 is reduced due to this misalignment between the side edges of the free layer 14 and the HB layer 20, which degrades the performance of the read head 10.

As the sidewall coverage improves, the thickness “b” decreases and the flaring of the read gap is reduced. Accordingly, the isolation layer 22 may be deposited by atomic layer deposition (ALD), which is capable of nearly 100 percent step coverage, so that the thickness “a” of the electrical insulator on the sidewall 24 is approximately equal to the thickness “b” in the field region. Although this improves the performance of the read head 10, deposition temperatures during the ALD process exceeding 130° C. hard bake the bi-layer resist mask 23 (FIG. 2A). This hard baking increases the adhesion between the lower resist layer 23a of bi-layer resist mask 23 and the read sensor 12, which interferes with the lift-off process used to remove the bi-layer resist mask 23. Limiting the deposition temperature below 130° C. leads to relatively poor film performance because of the concomitant elevated levels of impurities introduced into the electrical insulator constituting layer 22. For example, the low deposition temperatures cause relatively high levels of hydrogen and carbon impurities in Al₂O₃ that acts to increase the conductivity and leakage current density.

More significantly, the lift-off process used to form the isolation layer 22 sets a fundamental upper limit on the thickness of the isolation layer 22. Specifically, the lift-off process does not scale for forming sub-micron sized read sensors 10 and, in particular, smaller than about 250 nanometers, because the undercut beneath the upper resist layer 23a of bi-layer resist mask 23 becomes too small. Moreover, because of the characteristic 100 percent step coverage afforded by ALD, the electrical insulator in isolation layer 22 may completely fill the undercut beneath the upper resist layer 23a of bi-layer resist mask 23, which would render the lift-off process nearly impossible or, at the least, unreliable. Another limitation is that, with further reductions in the critical dimensions of the read sensor 12, the undercut beneath the upper resist layer 23a of bi-layer resist mask 23 will eventually become too small to support the overlayers of the HB layer 20 and isolation layer 22 and, therefore, result in unreliable lift-off.

What is needed, therefore, is an improved method and process for fabricating read sensors for read-write heads that overcomes these and other deficiencies of conventional fabrication methods and processes for such read sensors.

### SUMMARY OF THE INVENTION

In accordance with the present invention, methods are provided for fabricating a device structure for a read head of a mass storage device. A planarization process is employed to remove a resist mask, which is used in a preceding fabrication stage as an ion milling mask, when forming a read sensor of the read head. A polish stop layer, which is formed of a relatively hard and/or wear-resistant material, is strategically positioned so as to eliminate the need to lift-off the bi-layer resist mask with a conventional chemical-based process. By eliminating the conventional chemical lift-off, an electrical isolation layer of a material such as Al₂O₃ may be formed on the read sensor using atomic layer deposition (AID) performed at a temperature exceeding 130° C.

In one embodiment of one aspect of the present invention, the method includes forming a layer stack including multiple layers capable of operating as a read sensor, forming a polish stop layer on the layer stack, and then defining a read sensor from the layer stack that is covered by a portion of the polish stop layer. After the read sensor is defined, an isolation layer including an electrical insulator is formed on the polish stop layer portion and the read sensor. A hard bias layer including a magnetic material is then formed on the isolation layer. The isolation layer and the hard bias layer are planarized using, for example, chemical mechanical polishing. The planarization stops vertically on the polish stop layer portion.

In an embodiment of another aspect of the present invention, the method includes forming a layer stack including multiple layers capable of operating as a read sensor, forming a polish stop layer on the layer stack, and forming a resist mask on the polish stop layer. A read sensor is formed from the layer stack at one of the locations masked by the resist mask. The read sensor and resist mask are separated by a residual portion of the polish stop layer. An isolation layer of an electrical insulator is formed on the polish stop layer portion, the resist mask, and the read sensor by an atomic layer deposition (ALD) process, which may be performed at a temperature exceeding 130° C.

### BRIEF DESCRIPTION OF THE DRAWINGS

The accompanying drawings, which are incorporated in and constitute a part of this specification, illustrate embodiments of the invention and, together with a general description of the invention given above and the detailed description of the embodiments given below, serve to explain the principles of the invention.

FIG. 1 is a view of a portion of a prior art mass storage device including a current-perpendicular-to-plane read head;

FIG. 2A is a cross-sectional view of a portion of a prior art fabrication process for forming the current-perpendicular-to-plane read head in the mass storage device of FIG. 1;

FIG. 2B is a cross-sectional view similar to FIG. 2A of the prior art current-perpendicular-to-plane read head after fabrication is completed;

FIGS. 3-9 are diagrammatic cross-sectional views of a portion of a substrate at various stages of a processing method for forming a read head in accordance with an embodiment of the invention; and

FIG. 10 is a diagrammatic view of a mass storage device incorporating the read head of FIG. 9.

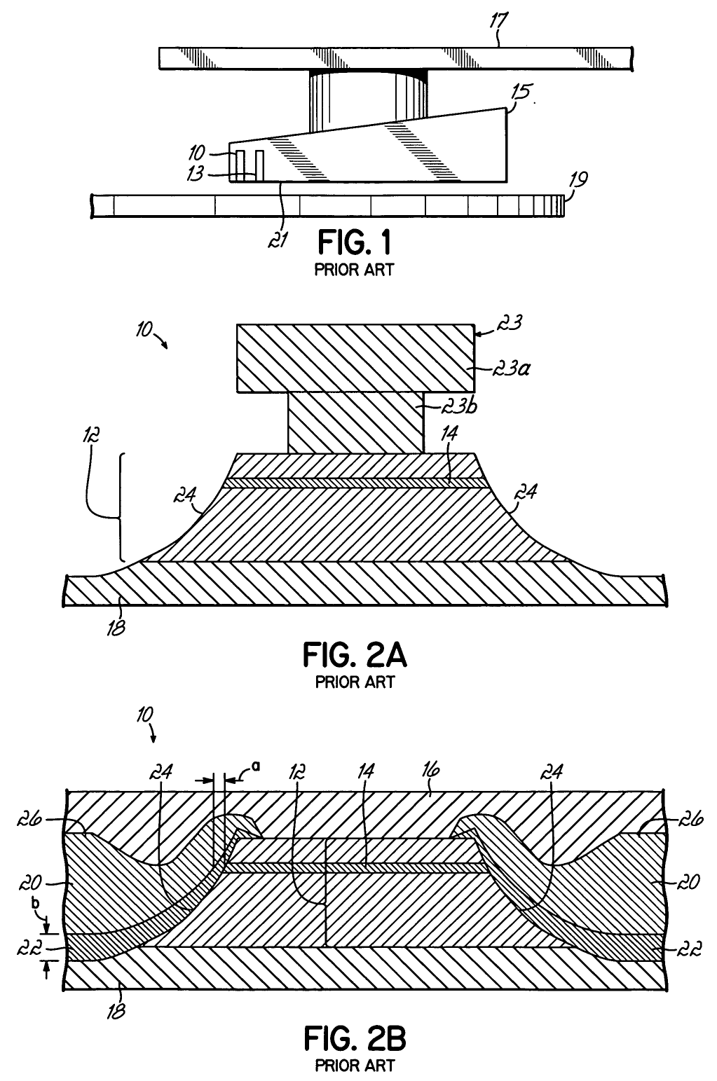

### DETAILED DESCRIPTION

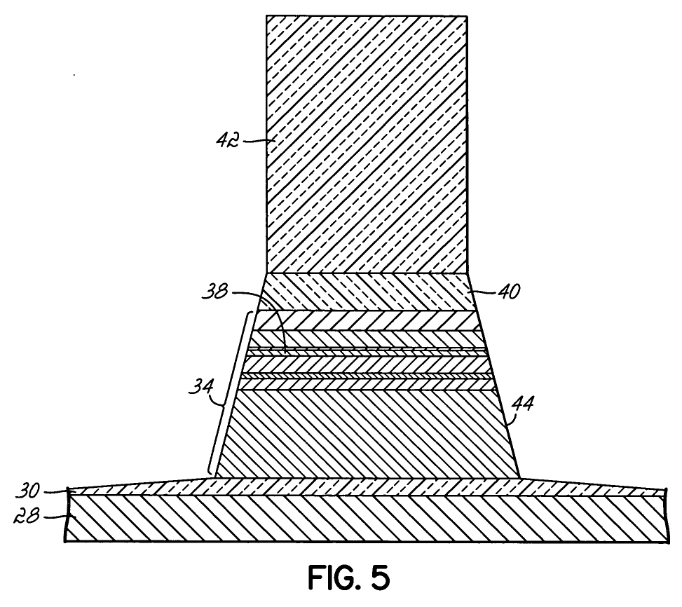

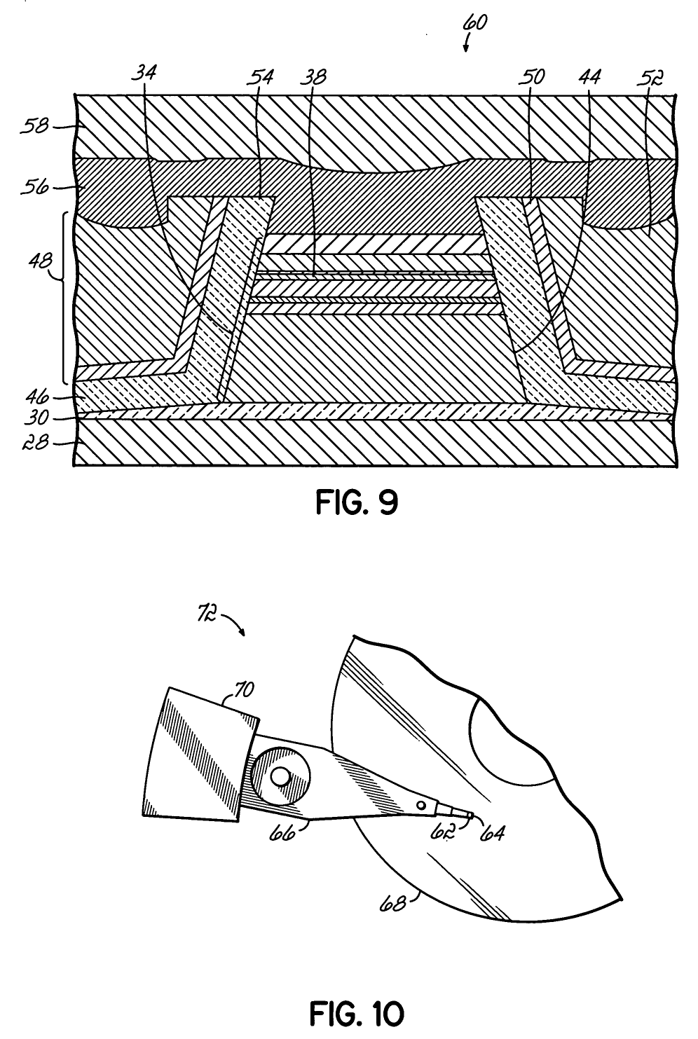

With reference to FIG. 3, a substrate (not shown), on which a number of read sensors 34 (FIG. 5) each destined for use in a read head 60 (FIG. 9) of a mass storage device are to be formed, is covered by a bottom magnetic shield 28. The substrate, which is typically disk-shaped, may be formed from any suitable non-magnetic metal or alloy including, but are not limited to, an alloy of aluminum, titanium and carbon (AlTiC). The bottom magnetic shield 28 is formed from any suitable conventional material, such as a nickel-iron alloy. The bottom magnetic shield 28 is then covered by an insulating layer 30 composed of any dielectric material recognized as suitable for this use by a person of ordinary skill in the art.

A layer stack 32 including a plurality of thin films is formed on the insulating layer 30 in which each individual thin film is formed by a suitable conventional deposition process, such as sputter deposition or an ion beam deposition (IBD) process. The layer stack 32 is shaped by a subsequent process to define a plurality of read sensors 34 (FIG. 5) at locations distributed across the surface of the substrate. Typically, the layer stack 32 has a thickness in the range of about 200 Å to 400 Å.

Each read sensor 34 (FIG. 5) may be any sensor operative to sense magnetic fields from a magnetic medium. Accordingly, the thin films in layer stack 32 have compositions, thicknesses, and an arrangement suitable to define a read sensor 34 preferably having a current-perpendicular-to-plane (CPP) geometry. The read sensor 34 may be constructed as any of a plurality of magnetoresistive (MR)-type sensors, including, but not limited to, AMR (anisotropic magnetoresistive), spin valve or GMR (giant magnetoresistive), TMR (tunnel magnetoresistive), ferromagnetic/nonmagnetic multi-layer ([FM/NM]ₙ) architectures. One or more layers 36 in the layer stack 32 becomes a sensing layer or free layer 38 (FIG. 5) of the fabricated read sensor 34 having a magnetization direction free to respond to an applied magnetic field. For example, the free layer 38 of a read sensor 34 operating as a TMR sensor is composed of two layers 36 of a ferromagnetic material, such as nickel-iron, cobalt-iron, or nickel-iron-cobalt, that differ in composition. The layer stack 32 also includes a layer of a material (not shown) that becomes a magnetization pinned layer of the read sensor 34 in which a magnetization is fixed in the applied magnetic field and a spacer layer (not shown) separating the free layer 38 from the pinned layer.

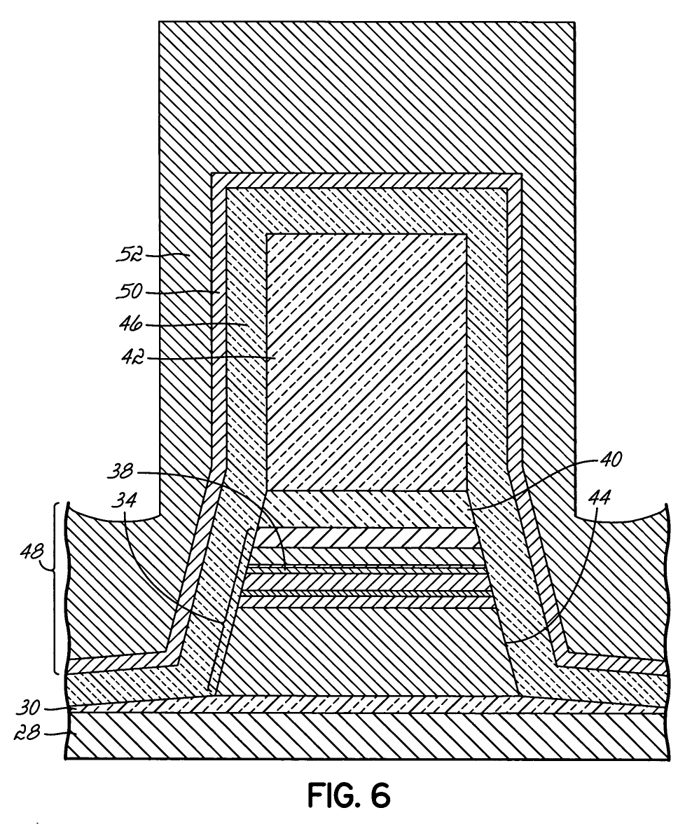

A polish stop layer 40 is formed on the layer stack 32. The polish stop layer 40 includes a material having a hardness and/or wear resistance sufficient to operate as a polish stop during planarization, as understood by a person of ordinary skill in the art. The polish stop layer 40 may be any material having a removal rate under planarization slower than a removal rate of an isolation layer 46 and an HB layer 48 (FIG. 6) under equivalent planarization conditions and that effectively operates as a stop layer during planarization. The polish stop layer 40 operates to protect the read sensor 34 from damage during a subsequent planarization step of the fabrication process. The thickness of the polish stop layer 40 may be equal or greater than fifty (50) Å and, preferably, is in the range of about fifty (50) Å to about one hundred (100) Å. The polish stop layer 40 is removed from the structure during a subsequent process step and, consequently, is not present in a fabricated read head 60 (FIG. 9).

Suitable materials for polish stop layer 40 include diamond-like carbon (DLC) formed by a conventional process like methane direct IBD, dual ion beam sputtering, radiofrequency or direct current excited hydrocarbon glow discharges, IBD or hydrocarbon glow discharge on an underlying silicon seed layer, and a filtered cathode arc (FCA) process. Preferably, the DLC is either hydrogenated DLC formed by direct ion beam deposition IBD, dual ion beam sputtering, radiofrequency-excited hydrocarbon glow discharge, or direct current-excited hydrocarbon glow discharge, or tetrahedral amorphous (ta-C) DLC formed by a filter cathode arc (FCA) process. DLC is a relatively hard material with low wear under abrasion and is inert chemically when exposed to the slurries used in CMP.

The material constituting polish stop layer 40 has a lower wear (i.e., a greater wear resistance) and/or a greater hardness than the constituent materials forming the isolation and HB layers 46, 48. In one embodiment of the present invention, the hardness of the constituent material of polish stop layer 40 is greater than about 10 gigapascals (GPa). Depending upon the specific forming process, the hardness of DLC for use as the polish stop layer 40 may be in the range of 10 GPa to about 70 GPa.

With reference to FIG. 4 in which like reference numerals refer to like features in FIG. 3 and at a subsequent fabrication stage, a resist mask 42 is formed by a conventional photolithographic patterning process on the polish stop layer 40. The resist mask 42 may be either a single-layer or multi-layer structure either and either include or omit an undercut. Because the present invention does not rely on a conventional lift-off process with chemical-based resist removal, the resist mask 42 may be structured and the composition of resist mask 42 selected without regard to the need to promote removal by lift-off in a subsequent fabrication stage. Read sensors 34 (FIG. 5) are defined in the layer stack 32 at locations protected from ion milling by the patterning of the resist mask 42.

With reference to FIG. 5 in which like reference numerals refer to like features in FIG. 4 and at a subsequent fabrication stage, an ion beam milling process (i.e., argon sputter etch) is used to define the read sensor 34 from the layer stack 32 at protected or masked locations defined within the pattern of resist mask 42. The ion beam milling process may use multiple incidence angles and multiple energies to define the read sensor 34. In one embodiment of the present invention, a first ion beam milling process uses argon ions with a kinetic energy of about 600 electron volts (eV) to about 1200 eV incident at an angle of between 30° and 15° degrees from the surface normal and a subsequent second ion beam milling process uses argon ions with a kinetic energy of about 100 eV to about 400 eV incident at an angle of between 75° and 60° to clean the re-deposited materials from a sidewall 44 of the read sensor 34 and, thereby, avert formation of a magnetic dead layer. The read sensor 34 includes the free layer 38 and is covered by a residual thickness of the polish stop layer 40 that is also protected by the resist mask 42 during ion milling. The ion milling process removes material until the vertical level of the insulating layer 30 and/or bottom magnetic shield 28 is reached.

With reference to FIG. 6 in which like reference numerals refer to like features in FIG. 5 and at a subsequent fabrication stage, the isolation layer 46 composed of an electrical insulator is formed, preferably conformally, on the layer stack 32 and resist mask 42 of the partially fabricated structure of FIG. 5. Preferably, the electrical insulator forming isolation layer 46 is alumina (Al₂O₃) and is formed by an atomic layer deposition (ALD) process. The ALD process is a conventional deposition technique in which deposition of each atomic layer of alumina, or a fraction thereof, is controlled by alternating and sequential introduction of appropriate gas phase precursors that react in a self-limiting manner to incrementally form or build isolation layer 46. One set of gas phase precursors that may be used to form Al₂O₃ by an ALD process is water vapor and trimethylaluminum (Al(CH₃)₃ or TMA).

The ALD process, which may be used to form the isolation layer 46, may be performed at a relatively high temperature within a broad temperature window that may extend as high as an upper limit of about 230° C. and, preferably, that exceeds 130° C. In conventional processes that rely on resist lift-off, the upper temperature limit on ALD processes is significantly lower because of adverse thermal effects that negatively impact resist lift-off. The elevated temperatures for the ALD process used in the present invention, which does not rely on lift-off, permit the isolation layer 46 to be formed with a reduced impurity content, which improves the performance of the read sensor 34 by reducing leakage current. However, the invention is not so limited as the ALD process may be performed at a lower temperature if impurity content is not a concern and/or to gain the advantages offered by the presence of the polish stop layer 40. In addition, other deposition processes, preferably processes that are capable of conformal deposition, may be used to form the isolation layer 46 while gaining the advantages offered by the presence of the polish stop layer 40.

The hard bias (HB) layer 48 is deposited, preferably conformally, on the isolation layer 46. In the illustrated embodiment of the present invention, the HB layer 48 includes a seed layer 50 and a “hard” magnetic layer 52 formed on the seed layer 50. The seed layer 50 may be chromium (Cr), titanium (Ti), a titanium chromium alloy (TiCr), a titanium tungsten alloy (TiW), or any other suitable material capable of providing an appropriate epitaxial template for the overlying magnetic layer 52. The “hard” magnetic material constituting magnetic layer 52 may be a cobalt-chromium-platinum alloy (CoCrPt), a cobalt-platinum alloy (CoPt), or any other material with the magnetic properties appropriate for use in the read sensor 34. Generally, the “hard” magnetic material may be any material in which a magnetization orientation is maintained when exposed to relatively low magnetic fields used during operation of the read sensor 34. The invention contemplates that the HB layer 48 may be formed from a single material as one individual layer, as opposed to the bilayer construction shown in FIG. 6.

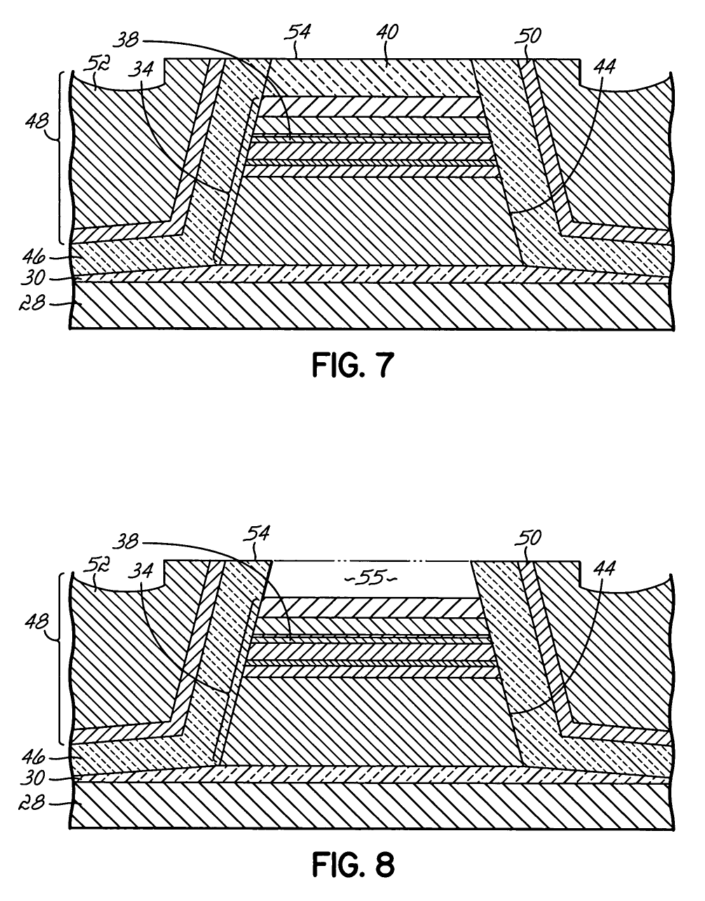

An exposed surface 54 of the HB layer 48 is uneven after the isolation layer 46 and the HB layer 48 are applied, preferably conformally, across the projecting read sensors 34 and the recessed surface areas between adjacent read sensors 34 in which the insulating layer 30 is exposed after ion milling. This unevenness of the surface topography is reduced by a subsequent planarization process (FIG. 7) that relies on the polish stop layer 40 to control the depth of material removal.

With reference to FIG. 7 in which like reference numerals refer to like features in FIG. 6 and at a subsequent fabrication stage, the exposed surface 54 is smoothed and flattened by a conventional planarization technique. One suitable planarization technique is a conventional chemical-mechanical polishing (CMP) process used in the microelectronics industry that affects material removal using a polishing pad and an abrasive slurry. The planarization process removes the overburden of excess material from isolation layer 46 and HB layer 48 covering the read sensors 34 and removes the resist mask 42. Consequently, the resist mask 42 does not require a conventional lift-off process for removal.

The planarization stops vertically at the level of the polish stop layer 40 because the material constituting the polish stop layer 40 has a greater hardness and, preferably, a significantly greater hardness than the materials constituting the resist mask 42, the isolation layer 46, and the HB layer 48. The exposed surface 54 may retain some surface topography after planarization. The residual HB layer 48 longitudinally stabilizes the free layer 14 and the remnants of the isolation layer 46 define a gap layer in the completed read head 60.

With reference to FIG. 8 in which like reference numerals refer to like features in FIG. 7 and at a subsequent fabrication stage, the polish stop layer 40 is removed from the partially fabricated structure. The removed polish stop layer 40 leaves behind a cavity or void 55, which is filled in a subsequent fabrication stage by a conductor, and exposes the top of the read sensor 34. If, for example, the polish stop layer 40 is DLC, a dry etch process, such as a plasma process or a reactive ion beam etch (RIBE) process, using a process gas of oxygen, a mixture of argon and oxygen, or a fluorine-containing gas, may be used to controllably remove the DLC layer with a high selectively to the other materials exposed to the dry etch process, which results in effective removal without damaging the top layer of the read sensor 34.

With reference to FIG. 9 in which like reference numerals refer to like features in FIG. 8 and at a subsequent fabrication stage, an electrical lead or upper electrode 56 is formed on the partially fabricated structure of FIG. 8. The upper electrode 56 is composed of a conductor, such as amorphous tantalum (α-Ta), rhodium (Rh), ruthenium (Ru), or a trilayer structure consisting of tantalum and gold (Ta/Au/Ta). A portion of the conductor of the upper electrode 56 fills the void 55 previously occupied by the material of the polish stop layer 40 and, thereby, establishes an electrical contact with high conductivity with the top thin film of the read sensor 34. A top shield 58 of a suitable conventional material, such as a nickel-iron (Ni—Fe) alloy, is formed on the upper electrode 56 by a conventional deposition technique. A resulting read head 60 is used in a read-write head of a mass storage device 72 (FIG. 10) for reading magnetically-encoded data stored by the device's media layer.

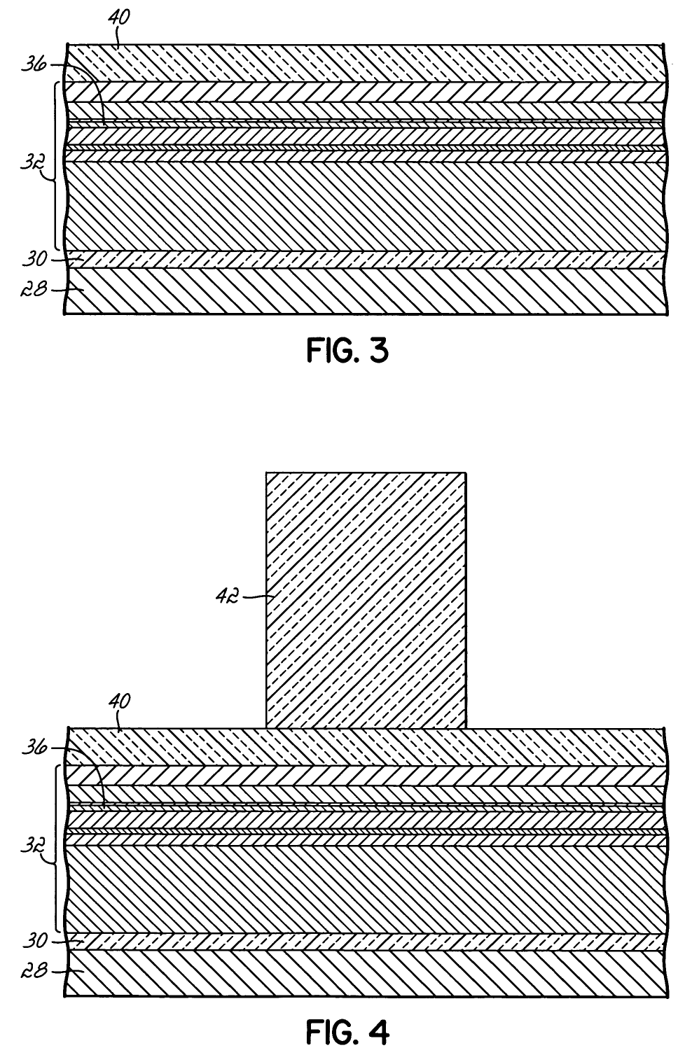

Because the isolation layer 46 has a substantially uniform thickness on the sidewall 44 of the read sensor 34 and in field regions remote from the read sensor 34, the midplane of the HB layer 48 is located at approximately the same horizontal level as the midplane and side edges of the free layer 38. In contrast to conventional read heads 10 (FIG. 2B), the stability of the free layer 38 is significantly improved because of the good alignment between the free layer 38 and the HB layer 48.

In accordance with the principles of the invention, the RIBE, ALD, and IBD processes used to fabricate the read head 60 may be performed in a single process tool platform without breaking vacuum. The integration of these diverse processes has the benefit of reducing any oxidation of the metal layers in the sensor stack, which occurs in a non-integrated platform when the structure is exposed to atmosphere during chamber transfers between processes. This oxidation, which the present invention may minimize or eliminate, can lead to poor control of the track width and the hard bias/free layer spacing in deep sub-micron read sensors 34. A tool that integrates IBE, ALD and IBD processes is the NEXUS cluster tool platform commercially available from Veeco Instruments Inc. (Plainview, N.Y.).

The isolation layer 46 may be formed using ALD, which provides nearly 100 percent step coverage and, hence, results in excellent electrical isolation performance. The digitized atomic layer by atomic layer growth afforded by the ALD process permits precise control over the thickness of isolation layer 46 and, therefore, the spacing or relative verticality of the HB layer 48 relative to free layer 38. This permits effective biasing, minimizes flaring of read gap, and improves the performance of the read sensor 34. The isolation layer 46 is also free of any inboard/outboard asymmetries, as may be observed in many conventional IBD processes, due to the nature of the ALD process.

The presence of the polish stop layer 40 affords precise and reliable control of the planarization process of FIG. 7. The presence of the polish stop layer 40, which permits the use of a planarization process for removing resist mask 42, also eliminates the need to chemically remove the resist mask 42 after the isolation layer 46 is formed. Thus, an ALD process forming isolation layer 46 may be performed at a higher temperature than in conventional processes because hard baking the resist mask 42 is not a concern. In instances in which the polish stop layer 40 is formed from DLC, a simple oxygen, argon/oxygen, or fluorine based plasma may be used to effect DLC removal selective to the other materials exposed to the plasma in the partially fabricated structure at this fabrication stage. These specific plasma chemistries have the ability to completely and cleanly remove the DLC in the polish stop layer 40, which promotes the establishment of a contact characterized by a high electrical conductivity between the upper electrode 56 and the read sensor 34.

With reference to FIG. 10 in which like reference numerals refer to like features in FIG. 9 and at a subsequent fabrication stage, the read head 60 is incorporated into the mass storage device 72. To that end, after the read head 60 (FIG. 9) and write head (not shown) have been created to define a read-write head 64, the supporting substrate is cut into strips and shaped into a slider 62. The slider 62 also includes a write head (not shown) and other structures (e.g., an air-bearing surface) required for operation of the read-write head 64. The slider 62 is suspended above a rotatable platter 68 from the free end of an actuator arm 66. The platter 68 includes a media layer suitable for storing magnetically-encoded data. An actuator 70 swings the actuator arm 66 to place the read head 60 of read-write head 64 over a selected data track in the media layer on the rotating platter 68. The read head 60 reads magnetically-encoded data from the media layer of the platter 68, which is written to the media layer of the platter 68 by the write head in a preceding write operation and stored by the media layer for future use. The read head 60 and write head of mass storage device 72 are connected to circuitry (not shown) that operates under computer control to implement the writing and reading operations.

References herein to terms such as “vertical”, “horizontal”, etc. are made by way of example, and not by way of limitation, to establish a frame of reference. The term “horizontal” as used herein is defined as a plane parallel to the conventional plane or surface of the substrate, regardless of the actual spatial orientation of the substrate. The term “vertical” refers to a direction perpendicular to the horizontal, as just defined. Terms, such as “on”, “above”, “below”, “side” (as in “sidewall”), “higher”, “lower”, “over”, “beneath” and “under”, are defined with respect to the horizontal plane. It is understood that various other frames of reference may be employed for describing the present invention without departing from the spirit and scope of the present invention.

The fabrication of the device structure herein has been described by a specific order of fabrication stages and steps. However, it is understood that the order may differ from that described. For example, the order of two or more fabrication steps may be switched relative to the order shown. Moreover, two or more fabrication steps may be conducted either concurrently or with partial concurrence. In addition, various fabrication steps may be omitted and other fabrication steps may be added. It is understood that all such variations are within the scope of the present invention.

While the present invention has been illustrated by a description of various embodiments and while these embodiments have been described in considerable detail, it is not the intention of the applicants to restrict or in any way limit the scope of the appended claims to such detail. Additional advantages and modifications will readily appear to those skilled in the art. Thus, the invention in its broader aspects is therefore not limited to the specific details, representative apparatus and method, and illustrative example shown and described. Accordingly, departures may be made from such details without departing from the spirit or scope of applicants' general inventive concept.

What is claimed is:

1. A method of fabricating a device structure, comprising:
forming a layer stack including multiple layers capable of operating as a read sensor;
forming a polish stop layer on the layer stack;
defining a read sensor from the layer stack, wherein the read sensor is covered by a portion of the polish stop layer;
forming an isolation layer including an electrical insulator on the polish stop layer portion and the read sensor;
forming a hard bias layer including a magnetic material on the isolation layer;
planarizing the isolation layer and the hard bias layer; and
stopping the planarization on the polish stop layer portion.

2. The method of claim 1 wherein planarizing the isolation layer and the hard bias layer further comprises:
polishing the isolation layer and the hard bias layer with a chemical-mechanical polish process.

3. The method of claim 1 wherein a material forming the polish stop layer has a lower wear than respective materials forming the hard bias layer and the isolation layer.

4. The method of claim 1 wherein the polish stop layer is composed of a material having a hardness greater than 10 gigapascals.

5. The method of claim 1 wherein the polish stop layer is diamond-like carbon.

6. The method of claim 5 wherein the diamond-like carbon is hydrogenated diamond-like carbon deposited by a technique selected from the group consisting of direct ion beam deposition, dual ion beam sputtering, a radiofrequency-excited hydrocarbon glow discharge, and a direct current-excited hydrocarbon glow discharge.

7. The method of claim 5 wherein the diamond-like carbon is tetrahedral amorphous (ta-C) diamond-like carbon deposited by a filtered cathodic arc process.

8. The method of claim 1 further comprising:
removing the polish stop layer portion after planarizing the isolation layer and the hard bias layer.

9. The method of claim 8 wherein removing the polish stop layer further comprises:
exposing the polish stop layer portion by a dry etch process effective to remove the polish stop layer selectively to the isolation layer and the hard bias layer.

10. The method of claim 9 wherein the dry etch process is selected from the group consisting of a plasma process and a reactive ion beam etch process.

11. The method of claim 10 wherein the polish stop layer is diamond-like carbon, and the dry etch process uses a process gas selected from the group consisting of oxygen, a mixture of argon and oxygen, and a fluorine-containing gas.

12. The method of claim 8 further comprising:
forming an upper electrode of a conductor on the isolation layer and the hard bias layer after removing the polish stop layer portion, wherein the conductor of the upper electrode fills a void remaining after removal of the polish stop layer portion.

13. The method of claim 1 wherein defining the read sensor further comprises:
masking the polish stop layer and the layer stack with a resist mask; and
ion milling the polish stop layer and the layer stack to define the read sensor and the polish stop layer portion in locations masked by the resist mask.

14. The method of claim 13 further comprising:
removing the resist mask from the device structure when the isolation layer and the hard bias layer are planarized.

15. The method of claim 14 wherein the resist mask is completely removed from the device structure when the planarization stops on the polish stop layer portion.

16. The method of claim 13 wherein forming an isolation layer further comprises:
forming the isolation layer is formed by an atomic layer deposition (ALD) process.

17. The method of claim 16 wherein the ALD process is performed at a temperature exceeding 130° C.

18. The method of claim 1 wherein the layer stack includes a layer of a material having a magnetization direction free to respond to an applied magnetic field.

19. The method of claim 18 wherein the read sensor includes a free layer formed from the layer.

20. The method of claim 1 wherein the isolation layer is formed by an atomic layer deposition (ALD) process.

21. The method of claim 20 wherein the ALD process is performed at a temperature exceeding 130° C.

22. The method of claim 1 wherein the read sensor has an inclined sidewall, and forming the isolation layer further comprises:
forming the isolation layer with a substantially uniform thickness on the inclined sidewall.

23. A method of fabricating a device structure, comprising:
forming a layer stack including multiple layers capable of operating as a read sensor;
forming a polish stop layer on the layer stack;
forming a resist mask on the polish stop layer;
defining a read sensor from the layer stack at a location masked by the resist mask, wherein the read sensor and resist mask are separated by a portion of the polish stop layer; and
forming an isolation layer of an electrical insulator on the polish stop layer portion, the resist mask, and the read sensor by an atomic layer deposition (ALD) process.

24. The method of claim 23 further comprising:
forming a hard bias layer including a magnetic material on the electrical insulator layer;
planarizing the isolation layer, the hard bias layer, and the resist mask so that the resist mask is removed from the device structure; and
stopping the planarization on the polish stop layer portion.

25. The method of claim 24 further comprising:
removing the polish stop layer portion.

26. The method of claim 25 wherein removing the polish stop layer portion further comprises:
etching the polish stop layer portion selective a material forming an adjacent layer of the read sensor such that the adjacent layer of the read sensor is not damaged by removal of the polish stop layer.

27. The method of claim 23 wherein defining the read sensor further comprises:
ion milling the polish stop layer and the layer stack to define the read sensor and the polish stop layer portion in regions masked by the resist mask before forming the isolation layer.

28. The method of claim 23 wherein forming the isolation layer further comprises:
performing the (ALD) process at a temperature exceeding 130° C. to deposit the electrical insulator.
